(19) United States
(12) Patent Application Publication
(10) Pub. No.: US 2025/0124969 A1
(43) Pub. Date: Apr. 17, 2025

(54) MEMORY DEVICES AND OPERATING METHODS THEREOF

(71) Applicant: Samsung Electronics Co., Ltd., Suwon-si (KR)

(72) Inventors: Changyoung Lee, Suwon-si (KR); Yeongwoo Kang, Suwon-si (KR); Yongjun Kim, Suwon-si (KR)

(21) Appl. No.: 18/669,633

(22) Filed: May 21, 2024

(30) Foreign Application Priority Data
Oct. 12, 2023 (KR) 10-2023-0136219

(51) Int. Cl. G11C 11/4091; G11C 11/408

(52) U.S. Cl. CPC G11C 11/4091; G11C 11/4085

(57) ABSTRACT

Memory devices and methods of operating thereof. A memory device may include a plurality of memory cells each including a cell transistor having a back gate that is shared with a cell transistor of an adjacent memory cell through a back gate line, a forward gate that is connected to a corresponding word line, and a cell capacitor that is connected to a first electrode of the cell transistor; a sub-word line driver configured to apply a word line driving voltage to a selected word line; a back gate driver configured to change a back gate voltage applied to the back gate line from a first voltage level to a second voltage level during an active period in which the selected word line is enabled; and a sense amplifier configured to sense data through bit lines connected to second electrodes of the cell transistors of the plurality of memory cells.

### CROSS-REFERENCE TO RELATED APPLICATION

This application is based on and claims priority under 35 U.S.C. § 119 to Korean Patent Application No. 10-2023-0136219, filed on Oct. 12, 2023, in the Korean Intellectual Property Office, the disclosure of which is incorporated by reference herein in its entirety.

### BACKGROUND

The present disclosure relates to electronic devices, and more specifically, to memory devices that control or are configured to control a back gate voltage applied to a back gate in an active period and to methods of operating the memory devices.

Semiconductor memories are used widely to store data in various electronic devices, such as computers, wireless communication devices, or the like. One type of semiconductor memory, Dynamic Random Access Memory (DRAM), operates by writing and reading data using charges stored in a cell capacitor of a memory cell. In DRAM, an array of memory cells is connected with bit lines and word lines. The bit lines may be connected to a sense amplifier and the word lines may be connected to a word line driving circuit.

### SUMMARY

The present disclosure provides memory devices configured to adjust a voltage level of a voltage applied to a back gate line corresponding to an enabled word line and to operating methods of the memory devices.

According to some aspects of the present inventive concepts, there is provided a memory device including a plurality of memory cells, each memory cell including a cell transistor having a back gate that is shared with an adjacent cell transistor of an adjacent memory cell and connected to a back gate line, a forward gate that is connected to a word line, and a cell capacitor that is connected to a first electrode of the cell transistor; a sub-word line driver configured to apply a word line driving voltage to a selected word line, a back gate driver configured to change a back gate voltage applied to a back gate line corresponding to the selected back gate line from a first voltage level to a second voltage level during an active period in which the selected word line is enabled; and a sense amplifier configured to sense data through a bit line connected to a second electrode of the cell transistor.

According to some aspects of the present inventive concepts, there is provided a memory device including a cell array structure including a plurality of word lines, a plurality of bit lines, a plurality of back gate lines, and a plurality of memory cells, sharing a back gate line with an adjacent memory cell through a back gate line connected thereto, and a peripheral circuit structure including a peripheral circuit configured to apply a word line driving voltage to a selected word line among the plurality of word lines, configured to apply a back gate voltage to a back gate line connected to memory cells connected to the selected word line, and configured to sense data through at least one selected bit line among the plurality of bit lines, the peripheral circuit structure overlapping vertically with at least a portion of the cell array structure. The peripheral circuit may be configured to change a voltage level of the back gate voltage from a first voltage level to a second voltage level within an active period in which the selected word line is enabled.

According to some aspects of the present inventive concepts, there is provided a method of operating a memory device, the method including: during a first precharge period, applying a first word line driving voltage of a first driving voltage level to a plurality of word lines; during the first precharge period, applying a first back gate voltage of a first voltage level to a plurality of back gate lines; during an active period after the first precharge period, applying a second word line driving voltage of a second driving voltage level higher than the first driving voltage level to a selected word line among the plurality of word lines; and during the active period, applying a second back gate voltage of a second voltage level which is lower than the first voltage level to a back gate line among the plurality of back gate lines corresponding to the selected word line and connected to memory cells sharing a back gate.

### BRIEF DESCRIPTION OF THE DRAWINGS

The present inventive concepts and some examples of embodiments thereof will be more clearly understood from the following detailed description taken in conjunction with the accompanying drawings in which:

FIG. 1 is a block diagram of a memory device according to some embodiments;

FIG. 2 is a diagram schematically showing the structure of a memory device according to some embodiments;

FIG. 3 is a circuit diagram of a memory cell array according to some embodiments;

FIG. 4 is a diagram for explaining parasitic capacitors included in a memory cell array according to some embodiments;

FIG. 5 is a circuit diagram of a sense amplifier according to some embodiments;

FIG. 6 is a timing diagram of voltages applied to a word line, a bit line, and a back gate line according to some embodiments;

FIG. 7 is a circuit diagram of a sense amplifier according to some embodiments;

FIGS. 8, 9, 10, and 11 are timing diagrams of voltages applied to a word line, a bit line, and a back gate line according to some embodiments;

FIG. 12 is a timing diagram for explaining word line driving voltages applied to each of a selected word line and an adjacent word line according to some embodiments;

FIG. 13 is a timing diagram for explaining an enabled word line driving voltage according to some embodiments;

FIG. 14 is a diagram for explaining a back gate driver according to some embodiments;

FIG. 15 is a diagram schematically showing the structure of the back gate driver of FIG. 14;

FIG. 16 is a diagram for explaining a back gate driver according to some embodiments;

FIG. 17 is a diagram schematically showing the structure of the back gate driver of FIG. 16;

FIG. 18 is a diagram for explaining a back gate driver according to some embodiments;

FIG. 19 is a diagram schematically showing the structure of the back gate driver of FIG. 18;

FIG. 20 is a graph illustrating current according to back gate voltage according to some embodiments;

FIG. 21 is a flowchart illustrating a method of operating a memory device, according to some embodiments;

FIG. 22 is a flowchart illustrating a method of operating a memory device, according to some embodiments;

FIG. 23 is a flowchart illustrating a method of operating a memory device, according to some embodiments;

FIG. 24 is a diagram showing a layout of an integrated circuit device according to some embodiments;

FIG. 25 is a cross-sectional view taken along lines X1-X1′ and Y1-Y1′ of FIG. 24;

FIG. 26 is a layout diagram showing an integrated circuit device according to some embodiments;

FIG. 27 is a cross-sectional view taken along line X2-X2′ of FIG. 26; and

FIG. 28 is a cross-sectional view taken along line Y2-Y2′ of FIG. 26.

### DETAILED DESCRIPTION OF THE EMBODIMENTS

Hereinafter, embodiments of the present disclosure will be described in detail with reference to the accompanying drawings.

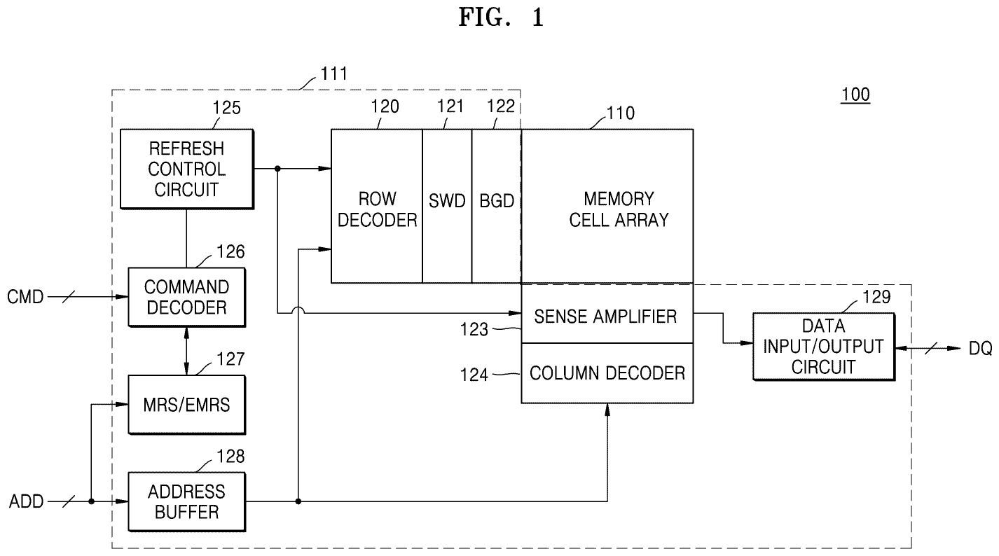

FIG. 1 is a block diagram of a memory device 100 according to some embodiments.

Referring to FIG. 1, the memory device 100 may correspond to, for example, Double Data Rate Synchronous Dynamic Random Access Memory (DDR SDRAM), Low Power Double Data Rate (LPDDR) SDRAM, Graphics Double Data Rate (GDDR) SDRAM, Rambus Dynamic Random Access Memory (RDRAM), or the like.

The memory device 100 may include a memory cell array 110 and a peripheral circuit 111.

The memory cell array 110 may include a plurality of memory cells arranged in rows and columns.

The peripheral circuit 111 may include a row decoder 120, a sub word line driver (SWD) 121, a back gate driver (BGD) 122, a sense amplifier 123, a column decoder 124, a refresh control circuit 125, a command decoder 126, a Mode Register Set/Extended Mode Register Set (MRS/EMRS) circuit 127, an address buffer 128, and a data input/output circuit 129.

The row decoder 120 may decode a row address of an address signal ADD that is output from the address buffer 128 and may designate a word line connected to a memory cell where data DQ is to be input or output. That is, in a data write mode or data read mode, the row decoder 120 may select a corresponding word line (which may be referred to herein as a selected word line) by decoding a row address that is output from the address buffer 128. Additionally, in a self-refresh mode, the row decoder 120 may select a corresponding word line by decoding a row address that is generated from an address counter (not shown) of the command decoder 126, discussed in greater detail herein.

The sub-word line driver 121 may apply a word line driving voltage to the selected word line. A voltage level of the word line driving voltage may vary depending on the operation period. For example, an operation period may include a precharge period and an active period. The precharge period may be a period during which the memory device 100 performs a precharge operation in response to a precharge command. The active period may be a period in which the memory device 100 performs various operations in response to an active command. Various operations in the active period may include, for example, a charge sharing operation, a sensing operation, a restore operation, or the like. For example, in the precharge period, a voltage level of the word line driving voltage applied to a specific (selected) word line may be a first voltage level, and in the active period, a voltage level of the word line driving voltage applied to the specific (selected) word line may be a second voltage level. A word line selected in the active period may be referred to herein as an enabled word line.

In some embodiments, the sub-word line driver 121 may apply a first word line driving voltage to a selected word line during an active period and may apply a second word line driving voltage to at least one adjacent word line during the active period. The at least one adjacent word line may be or may include a word line adjacent to the selected word line.

The back gate driver 122 may apply a back gate voltage to a back gate line. During a precharge period, the back gate driver 122 may apply a back gate voltage of a first voltage level to the back gate line. Within the active period, the back gate driver 122 may change the back gate voltage from a first level to a second level. The second level to which the back gate voltage changes in the active period may be differently set for each memory device 100. The back gate driver 122 may be implemented as a regulator, for example, a low dropout (LDO) regulator.

As used herein, reference to an event occurring during or in a period (e.g., an event occurring “during an active period” or “in a precharge period”) may be used to denote the even occurring at any point included in the period. For example, an event stated to occur during or in a specific period may be used to denote the event occurring at any point from the start of the specific period to the end of the specific period.

In some embodiments, the back gate driver 122 may restore or change the back gate voltage from the second level back to the first level in the active period.

In some other embodiments, the back gate driver 122 may restore or change the back gate voltage from the second level back to the first level in a precharge period after an active period.

The sense amplifier 123 may sense data of a memory cell of the memory cell array 110 through a bit line. The sense amplifier 123 may sense and amplify data DQ of the memory cell. The sense amplifier 123 may store the data DQ in the memory cell that is received from outside the memory device 100, and may be or may include a write driver, but the present disclosure is not limited thereto. The sense amplifier 123 may be implemented as a cross-coupled amplifier connected between a bit line included in the memory cell array 110 and a complementary bit line (bit line bar). A precharge operation, a charge sharing operation, a sensing operation, and/or a restore operation may be sequentially performed so that the sense amplifier 123 senses data DQ stored in the memory cell.

The column decoder 124 may decode a column address among address signals ADD that are output from the address buffer 128 in order to designate the bit line connected to the memory cell through which data DQ is to be input or output. The memory cell array 110 may output data from the memory cell designated by row and column addresses or write data into the memory cell.

The refresh control circuit 125 may control a self-refresh operation of the memory device 100 in response to a command output from the command decoder 126.

The command decoder 126 may include the address counter, a timer, and a core voltage generator, as non-limiting examples. The address counter may generate a row address, which may be a self-refresh target, in response to a self-refresh entry command that is output from the command decoder 126, and may apply the generated row address to the row decoder 120. The address counter may stop a counting operation in response to a self-refresh end command output from the command decoder 126.

The command decoder 126 may receive a command signal CMD applied from outside the memory device 100, decode the command signal CMD, and internally generate a decoded command signal, for example, a self-refresh entry command or a self-refresh exit command.

The MRS/EMRS circuit 127 may set an internal mode register in response to an MRS/EMRS command and an address signal ADD, which may designate an operation mode of the memory device 100. The MRS/EMRS circuit 127 may be programmed to set operating parameters, options, various functions, characteristics, and modes of the memory device 100. The MRS/EMRS circuit 127 may store a parameter code that may include bit values (e.g., appropriate bit values) provided by a command/address CA bus of a memory bus when an MRS command is issued from a memory controller coupled to the memory device 100.

For example, the MRS/EMRS circuit 127 may be used to control a burst length, a read/write latency, a dynamic voltage, a frequency scaling mode, or the like. The burst length may be provided to set a maximum number of column locations accessible for read and/or write commands. The read/write latency may be provided to define a clock cycle delay between a read and/or write command and a first bit of valid output and/or input data.

Data DQ input through the data input/output circuit 129 may be written into the memory cell array 110 based on the address signal ADD, and data DQ read from the memory cell array 110 based on the address signal ADD may be output to outside the memory device 100 through the data input/output circuit 129. An address signal ADD may be input to the address buffer 128 to designate a memory cell through which data will be written or read. The address buffer 128 may temporarily store the address signal ADD input from outside the memory device 100.

The memory device 100 may further include a clock circuit configured to generate a clock signal, a voltage detection circuit configured to detect a power generation circuit voltage level for generating or distributing an internal voltage by receiving a power voltage applied from outside the memory device 100, and a control circuit that is configured to control operations of the peripheral circuit 111.

According to some embodiments, there may be an effect of reducing leakage current that may occur in a memory cell, an effect of improving refresh characteristics of the memory device 100 according to reduced leakage current, and an effect of improving the reliability of the memory device 100 by adjusting the voltage level of a voltage applied to a back gate line in response to an enabled word line or selected word line.

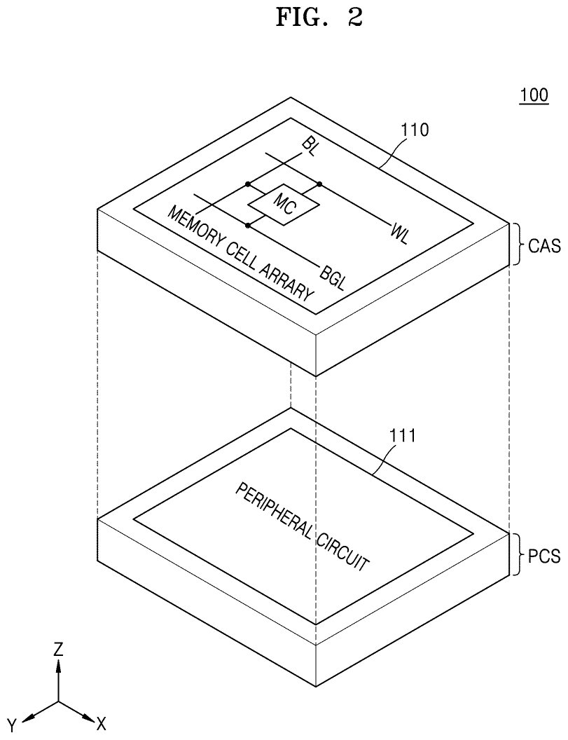

FIG. 2 is a diagram schematically showing the structure of a memory device 100 according to some embodiments.

Referring to FIG. 2, the memory device 100 may include a cell array structure CAS and a peripheral circuit structure PCS. The cell array structure CAS may be on top of the peripheral circuit structure PCS in a vertical direction (e.g., Z direction). That is, the peripheral circuit structure PCS may be covered and below the cell array structure CAS in a direction perpendicular to horizontal extension directions (e.g., X direction and Y direction) of the cell array structure CAS. In some embodiments, the cell array structure CAS and the peripheral circuit structure PCS may be bonded to each other through pads in the vertical direction (e.g., Z direction). The adhesion method may be, for example, bonding between copper (Cu) pads and copper (Cu) pads, but the present disclosure is not limited thereto.

The cell array structure CAS may include the memory cell array 110 of FIG. 1. The memory cell array 110 may include a plurality of word lines WL, a plurality of bit lines BL, and a plurality of back gate lines BGL connected to a plurality of memory cells MC. For example, the plurality of bit lines BL may extend in a first direction (e.g., Y direction) and may be arranged side-by-side in a second direction (e.g., X direction). Each of the plurality of word lines WL and the plurality of back gate lines BGL may extend in the second direction (e.g., X direction) and may be arranged parallel to each other in the first direction (e.g., Y direction). Each memory cell MC may be connected to a bit line BL of the plurality of bit lines BL, a word line WL of the plurality of word lines WL, and a back gate line BGL of the plurality of back gate lines BGL. Each memory cell MC may include a cell transistor and a cell capacitor. In some embodiments, the cell transistor of each memory cell MC may include a forward gate connected to a corresponding word line WL and a back gate connected to a corresponding back gate line BGL. Each memory cell MC may share a back gate with an adjacent memory cell through one back gate line BGL.

The peripheral circuit structure PCS may include the peripheral circuit 111 of FIG. 1. The peripheral circuit 111 may be configured to apply a word line driving voltage to a word line (e.g., WL) selected from among the plurality of word lines. The peripheral circuit 111 may be configured to apply a back gate voltage to a back gate line (e.g., BGL) connected to memory cells (e.g., MC) connected to a selected word line (e.g., WL). The peripheral circuit 111 may be configured to sense data through at least one bit line (e.g., BL) selected from among the plurality of bit lines.

Because the memory device 100 according to some embodiments may include the stacked cell array structure CAS and the peripheral circuit structure PCS, in the cell array structure CAS, word lines may be uninterrupted by circuit configurations other than memory cells but may extend in the cell array structure CAS.

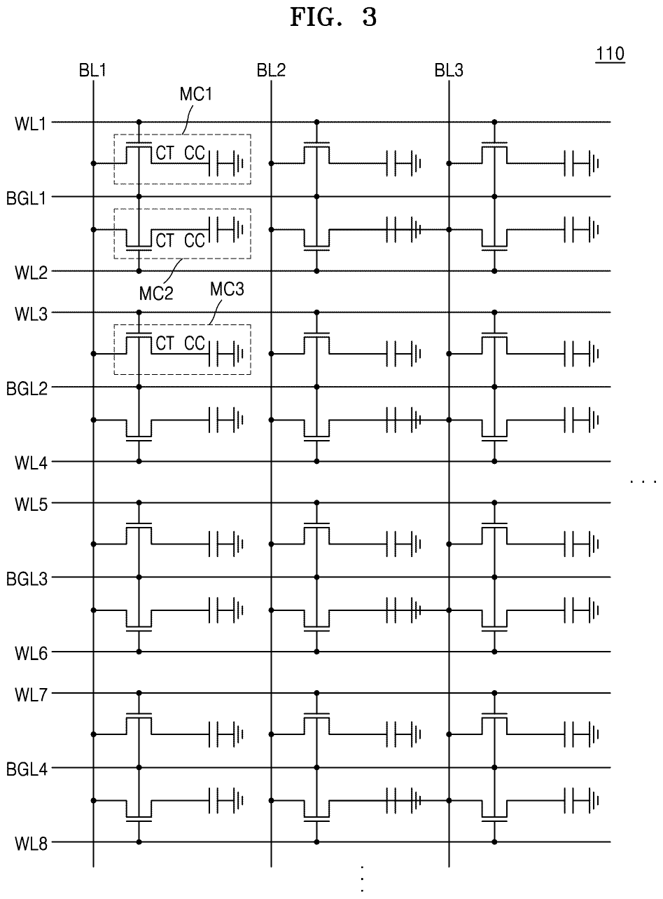

FIG. 3 is a circuit diagram of a memory cell array according to some embodiments.

Referring to FIGS. 2 and 3, the memory cell array 111 may include a plurality of word lines, a plurality of bit lines, a plurality of back gate lines, and a plurality of memory cells. Referring to FIG. 3, for example, first to eighth word lines WL1, WL2, WL3, WL4, WL5, WL6, WL7, and WL8, first to third bit lines BL1, BL2, and BL3, first to fourth back gate lines BGL1, BGL2, BGL3, and BGL4, and 24 memory cells are shown as an example in FIG. 3. However, the word lines, the bit lines, the gate lines, and the memory cells are not limited thereto.

Each of the plurality of memory cells may include a cell transistor CT and a cell capacitor CC. The cell transistor CT may include a plurality of electrodes, a forward gate connected to a corresponding word line WL, and a back gate connected to a back gate line BGL shared with an adjacent cell transistor CT. For example, the cell transistor CT of a first memory cell MC1 may include a forward gate connected to the first word line WL1, a back gate connected to the first back gate line BGL1, a first electrode connected to the cell capacitor CC of the first memory cell MC1, and a second electrode connected to the first bit line BL1. For example, the cell transistor CT of a second memory cell MC2 may include a forward gate connected to the second word line WL2, a back gate connected to the first back gate line BGL1, a first electrode connected to the cell capacitor CC of the second memory cell MC2, and a second electrode connected to the first bit line BL1. For example, the cell transistor CT of a third memory cell MC3 may include a forward gate connected to the third word line WL3, a back gate connected to the second back gate line BGL2, a first electrode connected to the cell capacitor CC of the third memory cell MC3, and a second electrode connected to the first bit line BL1. The cell transistor CT of the first memory cell MC1 and the cell transistor CT of the second memory cell MC2 may share a back gate line through the first back gate line BGL1. The cell transistor CT of the first memory cell MC1 and the cell transistor CT of the second memory cell MC2 may be adjacent cell transistors to each other. In some embodiments, a channel of the cell transistor CT may be formed in a vertical direction (e.g., Z direction). A cell transistor CT including a channel formed in a vertical direction (e.g., Z direction) may be referred to as a vertical channel transistor. In some embodiments, the cell transistor CT may be implemented as an n-type transistor, but the present disclosure is not limited thereto. If the cell transistor CT is provided with a back gate, a floating body may be controlled and a threshold voltage of the cell transistor CT may be controlled more easily. Additionally, when an adjacent cell transistor and a cell transistor CT share a back gate line, the chip size of the memory device 100 may be reduced and integration of the memory device 100 may be promoted. In some embodiments, a back gate line may be shared for every two word lines. However, the present disclosure is not limited thereto.

The cell capacitor CC of each memory cell may store charges of a capacity corresponding to a single bit of data (e.g., bit ‘0’ or bit ‘1’). According to some embodiments, the cell capacitor CC may store charges with a capacity corresponding to multi-bit data (e.g., 2-bit data). The cell capacitor CC may be restored to an amount of charge corresponding to the capacity of single bit data or multi-bit data. The cell capacitor CC may be connected between the first electrode and a ground of the cell transistor CT. For example, the first electrode of the cell capacitor CC may be connected to the first electrode of the cell transistor CT, and the second electrode of the cell capacitor CC may be connected to the ground.

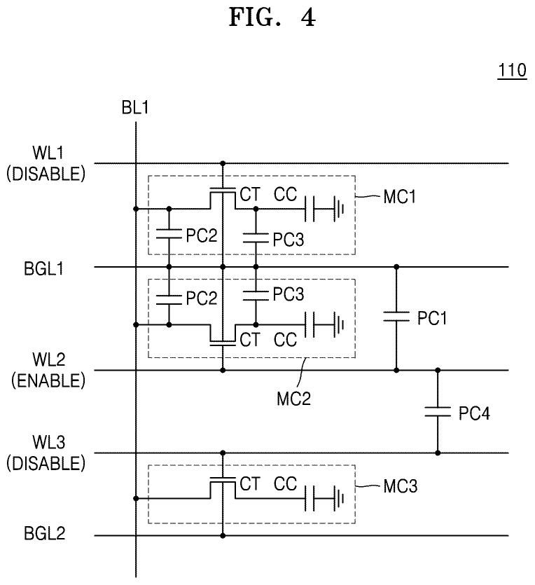

FIG. 4 is a diagram for explaining parasitic capacitors PC1, PC2, PC3, and PC4 included in the memory cell array according to some embodiments. For convenience of explanation, the parasitic capacitors PC1, PC2, PC3, and PC4 shown in FIG. 4 will be described below based on the first bit line BL1, the first and second word lines WL1 and WL2, the first and second back gate lines BGL1 and BGL2, and the first to third memory cells MC1, MC2, and MC3.

Referring to FIG. 4, the first and second memory cells MC1 and MC2 may be connected to the first back gate line BGL1, and the third memory cell MC3 may be connected to the second back gate line BGL2. When the second word line WL2 is selected, the second word line WL2 may be enabled. For example, a high voltage above a turn-on level for turning on the cell transistor CT of the second memory cell MC2 connected to the second word line WL2 may be applied to the second word line WL2 as a word line driving voltage. In this case, the first and third word lines WL1 and WL3 may be disabled. Because the first parasitic capacitor PC1 due to coupling exists between the first back gate line BGL1 and the second word line WL2, the potential of the first back gate line BGL1 may fluctuate or ripple as a word line driving voltage is applied to the second word line WL2. When the potential of the first back gate line BGL1 ripples, the potential of the first and second electrodes of the cell transistor CT of the first memory cell MC1 may also ripple, and the potential of the first word line WL1 may also ripple by the second and third parasitic capacitors PC2 and PC3 between the first back gate line BGL1 and the cell transistor CT of the first memory cell MC1. As a result, as the potential of the first word line WL1 also ripples, a threshold voltage of the cell transistor CT of the first memory cell MC1 may change (for example, decrease). When the threshold voltage of the cell transistor CT of the first memory cell MC1 is decreased, the cell transistor CT may be turned on, and thus, charges stored in the cell capacitor CC of the first memory cell MC1 may leak out to the first bit line BL through the turned-on cell transistor CT. That is, a leakage current may occur. If a leakage current occurs in the first memory cell MC1, the reliability of data stored in the first memory cell MC1 may be reduced.

When the selected second word line WL2 is enabled, the potential of the disabled third word line WL3 may ripple by the fourth parasitic capacitor PC4 between the second word line WL2 and the third word line WL3. As a result, as the potential of the third word line WL3 also ripples, a threshold voltage of the cell transistor CT of the third memory cell MC3 changes (for example, decreases) and a leakage current may occur at the third memory cell MC3.

In order to prevent the change of the threshold voltage of memory cells connected to the disabled word line, adjusting a voltage applied to the back gate line corresponding to the enabled word line may be performed.

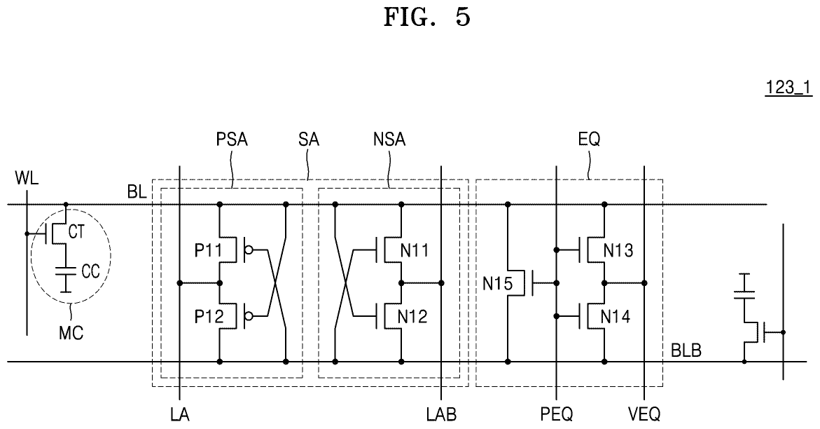

FIG. 5 is a circuit diagram of a sense amplifier 123_1 according to some embodiments.

Referring to FIG. 5, the sense amplifier 123_1 may include a bit line sense amplifier circuit SA and a precharge and equalization circuit EQ.

The bit line sense amplifier circuit SA may include a p-type sense amplifier PSA including p-type transistors, and an n-type sense amplifier NSA including n-type transistors.

The p-type sense amplifier PSA may include a first p-type transistor P11 and a second p-type transistor P12 connected in series between a bit line BL and a complementary bit line BLB. A first sensing driving voltage line LA may be connected to sources of the first and second p-type transistors P11 and P12. The complementary bit line BLB may be connected to a gate of the first p-type transistor P11. The bit line BL may be connected to a gate of the second p-type transistor P12. Sizes of the first p-type transistor P11 and the second p-type transistor P12 may be the same or different depending on the implementation. A first sensing driving voltage may be supplied through the first sensing driving voltage line LA, and the first sensing driving voltage of the bit line sense amplifier circuit SA may be a power supply voltage (VDD) (or an internal voltage generated inside the memory device 100) supplied to be used in an operation of the memory cell array 110. The p-type sense amplifier PSA connected to the first sensing driving voltage line LA may supply a high level of an amplified voltage level during a sensing and amplification operation of data of the memory cell MC connected to the bit line BL.

The n-type sense amplifier NSA may include a first n-type transistor N11 and a second n-type transistor N12 connected in series between the bit line BL and the complementary bit line BLB. A second sensing driving voltage line LAB may be connected to the sources of the first and second n-type transistors N11 and N12. The complementary bit line BLB may be connected to a gate of the first n-type transistor N11. The bit line BL may be connected to a gate of the second n-type transistor N12. Sizes of the first n-type transistor N11 and the second n-type transistor N12 may be the same or different depending on the implementation. A second sensing driving voltage may be supplied through the second sensing driving voltage line LAB, and the second sensing driving voltage of the bit line sense amplifier circuit SA may be a second power voltage VSS (e.g., ground voltage) of the memory device 100. The n-type sense amplifier NSA connected to the second sensing driving voltage line LAB may supply a low level of the amplified voltage level during the sensing and amplification operation of data of the memory cell MC connected to the bit line BL.

The precharge and equalization circuit EQ may equalize the bit line BL and the complementary bit line BLB to a bit line precharge voltage VEQ level in response to an equalizing signal PEQ. The precharge and equalization circuit EQ may include a third n-type transistor N13 connected between the bit line precharge voltage VEQ and the bit line BL, a fourth n-type transistor N14 connected between the bit line precharge voltage VEQ and the complementary bit line BLB, and a fifth n-type transistor N15 connected between the bit line BL and the complementary bit line BLB. According to some embodiments, the precharge and equalization circuit EQ may include one of the third n-type transistor N13 or the fourth n-type transistor N14, in addition to the fifth n-type transistor N15. Gates of the third to fifth n-type transistors N13 to N15 may be connected to the equalizing signal PEQ. The equalizing signal PEQ may be provided from a control logic circuit based on a command provided to the memory device 100. The equalizing signal PEQ may be applied at a logic high level during the precharge operation of the bit line sense amplifier circuit SA to turn on the first to third n-type transistors N13, N14, and N15, and may precharge the bit line BL and the complementary bit line BLB to the bit line precharge voltage VEQ level. During the sensing operation, the equalizing signal PEQ may be applied at a logic low level to turn off the first to third n-type transistors N13, N14, and N15.

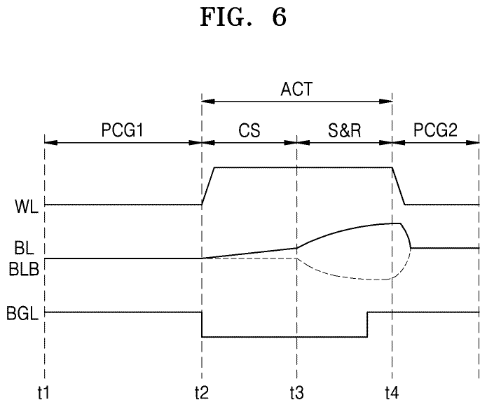

FIG. 6 is a timing diagram of voltages applied to a word line, a bit line, and a back gate line according to some embodiments.

Referring to FIGS. 1, 5, and 6, the precharge period may be a period in which the memory device 100 performs a precharge operation in response to a precharge command. A first precharge period PCG1 may be a period corresponding to a first time t1 to a second time t2. In the first precharge period PCG1, a voltage level of the word line driving voltage applied to the word line WL may be a first driving voltage level. At this time, the word line WL may be disabled. A bit line precharge voltage VEQ may be applied to the bit line BL and the complementary bit line BLB. The potential of the bit line BL and the complementary bit line BLB may be, for example, a half (VDD/2) the voltage level of the first power voltage VDD. A voltage level of the back gate voltage applied to the back gate line BGL may be a first voltage level.

An active period ACT may be a period during which the memory device 100 performs a charge sharing operation, a sensing operation, and a restoring operation in response to an active command. The active period ACT may include a charge sharing period CS and a sensing period and restoring period S&R. The active period ACT may be a period corresponding to the second time t2 to a fourth time t4. The charge sharing period CS may be a period from the second time t2 to the third time t3. The sensing period and restoring period S&R may be a period corresponding to the third time t3 to the fourth time t4. At the second time t2, a word line driving voltage of a second driving voltage level may be applied to the word line WL. In this case, the potential of the word line WL rises, and the word line WL may be enabled. The potential of one of the bit line BL and the complementary bit line BLB may rise, and the potential of the other of the bit line BL and the complementary bit line BLB may fall. In some embodiments, the voltage level of the back gate voltage applied to the back gate line BGL within the charge sharing period CS may change from a first voltage level to a second voltage level. For example, the first voltage level may be higher than the second voltage level. Reference to FIG. 6, for example, the voltage level of the back gate voltage may decrease from the first voltage level to the second voltage level from the second time t2. However, the time (e.g., the second time t2) at which the voltage level of the back gate voltage begins to decrease is not limited thereto, and the voltage level of the back gate voltage may decrease from the first voltage level to the second voltage level from any time between the second time t2 and the third time t3. At the third time t3, the potential of each of the bit line BL and the complementary bit line BLB may further rise or fall. In some embodiments, the voltage level of the back gate voltage applied to the back gate line BGL may return from the second voltage level to the first voltage level within the sensing period and restoring period S&R. For example, from any time between the third time t3 and the fourth time t4, the voltage level of the back gate voltage may increase from the second voltage level to the first voltage level. However, the time (e.g., any time between the third time t3 and the fourth time t4) at which the voltage level of the back gate voltage begins to increase is not limited thereto, and in some other embodiments, the voltage level of the back gate voltage may change from the second voltage level to the first voltage level within a second precharge period PCG2 after the sensing period and restoring period S&R. The second precharge period PCG2 may arrive after the active period ACT.

According to the embodiments described above, the refresh characteristics of the memory device 100 may be improved by reducing leakage current.

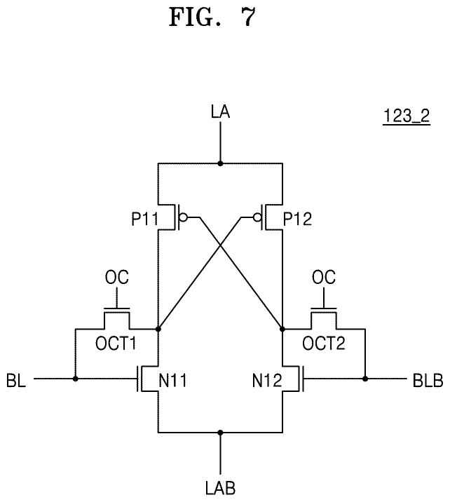

FIG. 7 is a circuit diagram of a sense amplifier 123_2 according to some embodiments. Specifically, FIG. 7 is a circuit diagram illustrating a bit line sense amplifier circuit and an offset cancellation circuit included in the sense amplifier 123_2.

Referring to FIG. 7, the sense amplifier 123_2 may include first and second p-type transistors P11 and P12, first and second n-type transistors N11 and N12, a first offset cancellation transistor OCT1, and a second offset cancellation transistor OCT2. The first and second p-type transistors P11 and P12 and the first and second n-type transistors N11 and N12 may be included in the bit line sense amplifier circuit SA of FIG. 5. Although not shown, the sense amplifier 123_2 may further include the precharge and equalization circuit EQ of FIG. 5.

The first p-type transistor P11 and the first n-type transistor N11 may be connected to each other and implemented as a first inverter. The second p-type transistor P12 and the second n-type transistor N12 may be connected to each other and implemented as a second inverter.

The first offset cancellation transistor OCT1 and the second offset cancellation transistor OCT2 may be devices for removing an offset of a threshold voltages of the first and second n-type transistors N11 and N12, respectively. The first offset cancellation transistor OCT1 and the second offset cancellation transistor OCT2 may operate in response to an offset cancellation signal OC. For example, the first offset cancellation transistor OCT1 and the second offset cancellation transistor OCT2 may be turned on by receiving the offset cancellation signal OC at a turn-on level. The offset cancellation signal OC may be generated by conjunction.

A first electrode of the first offset cancellation transistor OCT1 may be connected to a bit line BL. A second electrode of the first offset cancellation transistor OCT1 may be connected to a gate electrode of the second p-type transistor P12. A first electrode of the second offset cancellation transistor OCT2 may be connected to the complementary bit line BLB. A second electrode of the second offset cancellation transistor OCT2 may be connected to the gate electrode of the first p-type transistor P11.

The active period ACT may further include an offset cancellation period. As the first offset cancellation transistor OCT1 and the second offset cancellation transistor OCT2 are turned on in the offset cancellation period, the first and second n-type transistors N11 and N12 may operate as diodes.

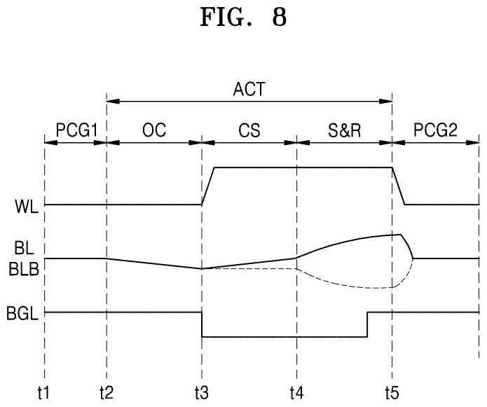

FIGS. 8, 9, 10, and 11 are timing diagrams of voltages applied to a word line, a bit line, and a back gate line according to some embodiments. In the description of each of the timing diagrams of FIGS. 8, 9, 10, and 11, the same descriptions previously given with reference to FIG. 6 will be omitted.

Referring to FIGS. 8, 9, 10, and 11, potentials of the word line WL, the bit line BL, and the complementary bit line BLB are as described with reference to FIG. 6. The active period ACT may further include an offset cancellation period OC. The offset cancellation period OC may be the period from the second time t2 to the third time t3 in FIG. 8.

A voltage level of a back gate voltage may be changed from a first voltage level to a second voltage level within the charge sharing period CS. In addition, a voltage level of the back gate voltage may be changed from the second voltage level to the first voltage level within any one of the active period ACT and the second precharge period PCG2 after the active period ACT.

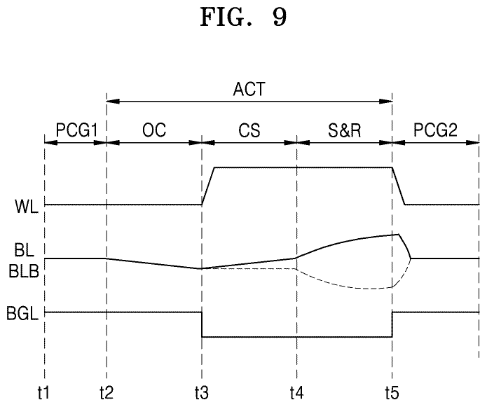

Referring to FIGS. 8 and 9, for example, within the charge sharing period CS (e.g., from any time between the third time t3 and the fourth time t4), a voltage level of the back gate voltage may be changed from the first voltage level to the second voltage level. Referring to FIG. 8, for example, within the sensing period and restoring period S&R (e.g., from any time between the fourth time t4 and the fifth time t5), the voltage level of the back gate voltage may be changed from the second voltage level to the first voltage level. Referring to FIG. 9, for example, within the second precharge period PCG2 (e.g., from the fifth time t5), the voltage level of the back gate voltage may be changed from the second voltage level to the first voltage level.

When the voltage level of the back gate voltage changes, a predetermined delay time may occur. According to the delay time, within a period between the first precharge period PCG1 and the charge sharing period CS in which the word line WL is disabled before the active period ACT, the voltage level of the back gate voltage may be changed from the first voltage level to the second voltage level. The period between the first precharge period PCG1 and the charge sharing period CS may be, for example, an offset cancellation period OC. The voltage level of the back gate voltage may be changed from the second voltage level to the first voltage level within any one of the active period ACT and the second precharge period PCG2.

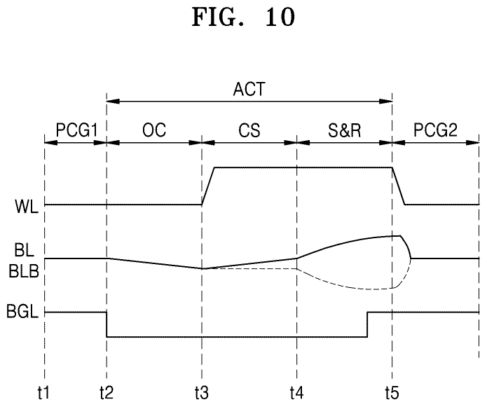

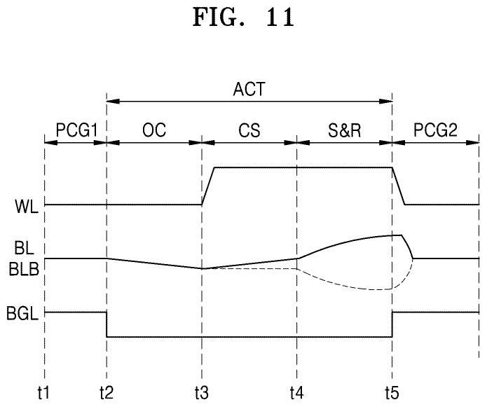

Referring to FIGS. 10 and 11, for example, within the offset cancellation period OC (e.g., from any time between the second time t2 and the third time t3), the voltage level of a back gate voltage may be changed from the first voltage level to the second voltage level. Referring to FIG. 10, for example, within the sensing period and restoring period S&R, the voltage level of the back gate voltage may be changed from the second voltage level to the first voltage level. Referring to FIG. 11, for example, from the fifth time t5 included in the second precharge period PCG2, the voltage level of the back gate voltage changes from the second voltage level to the first voltage level and the first voltage level may be maintained until the next active period ACT.

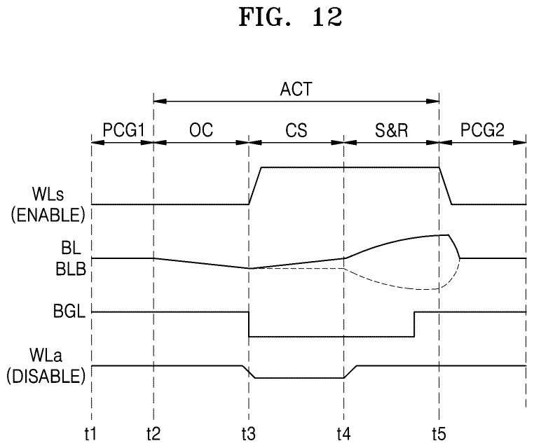

FIG. 12 is a timing diagram for explaining word line driving voltages applied to each of a selected word line and an adjacent word line according to some embodiments.

Referring to FIGS. 3, 4, and 12, the potentials of the bit line BL and the complementary bit line BLB are as described with reference to FIG. 6. The back gate voltage applied to the back gate line BGL may be changed as in the embodiments described above with reference to FIGS. 8 to 11.

In some embodiments, within the active period ACT in which the selected word line WLs is enabled, the voltage level of the word line driving voltage applied to the adjacent word line WLa may decrease. For example, it may be assumed that the selected word line WLs is the second word line WL2 in FIG. 2 and the adjacent word line WLa is the third word line WL3. At the time when the charge sharing period CS of the active period ACT starts, for example, at the third time t3, the potential of the second word line WL2 increases from the first driving voltage level to the second driving voltage level. In addition, at the third time t3, the voltage level of the word line driving voltage applied to the third word line WL3 may decrease. That is, the potential of the third word line WL3 may decrease. At the time when the sensing period and restoring period S&R starts, for example, at the fourth time t4, the voltage level of the word line driving voltage applied to the third word line WL3 may increase. That is, the potential of the third word line WL3 may increase. The potential of the third word line WL3 after the fourth time t4 may be the same as the potential of the third word line WL3 before the third time t3. As described above with reference to FIG. 4, this may be to prevent the increase in the potential of the third word line WL3 by the fourth parasitic capacitor PC4 as the second word line WL2 is enabled. Therefore, by preventing the decrease in the threshold voltage of adjacent memory cells connected to the disabled adjacent word line, there may be an effect of reducing leakage current occurring in adjacent memory cells.

In FIG. 12, the active period ACT further includes an offset cancellation period OC, but the offset cancellation period OC may be omitted as shown in FIG. 6.

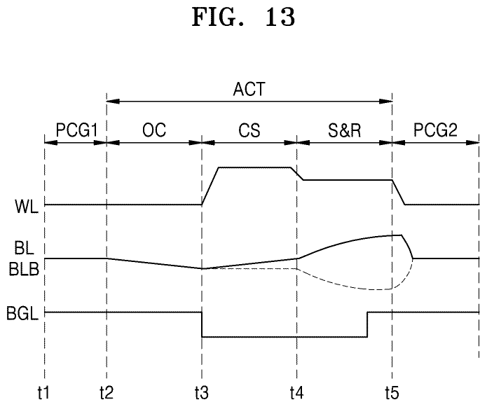

FIG. 13 is a timing diagram for explaining an enabled word line driving voltage according to some embodiments.

Referring to FIGS. 3 and 13, the potentials of the bit line BL and the complementary bit line BLB are as described with reference to FIG. 6. The back gate voltage applied to the back gate line BGL may be changed as in the embodiments described above with reference to FIGS. 8 to 11.

In some embodiments, within the active period ACT, a voltage level of the word line driving voltage may increase from a first driving voltage level to a third driving voltage level. That is, the potential of the word line WL may increase from the first driving voltage level to the third driving voltage level. The third driving voltage level may be higher than a second driving voltage level for turning on the cell transistor CT. The second driving voltage level may be a voltage level higher than a turn-on level for turning on. For example, in the first precharge period PCG1, the potential of the word line WL may be the first driving voltage level. In the charge sharing period CS, the potential of the word line WL may be the third driving voltage level. In the sensing period and restoring period S&R, the potential of the word line WL may be a driving voltage level (e.g., a second driving voltage level) lower than the third driving voltage level. In the second precharge period PCG2, the potential of the word line WL may be the first driving voltage level. Referring to FIG. 4, for example, as the selected second word line WL2 is enabled, the back gate voltage applied to the first back gate line BGL1 may decrease. This may prevent the decrease in on-cell current generated in memory cells connected to the enabled second word line WL2. As a result, there is an effect of preventing a decrease in on-cell current and reducing leakage current.

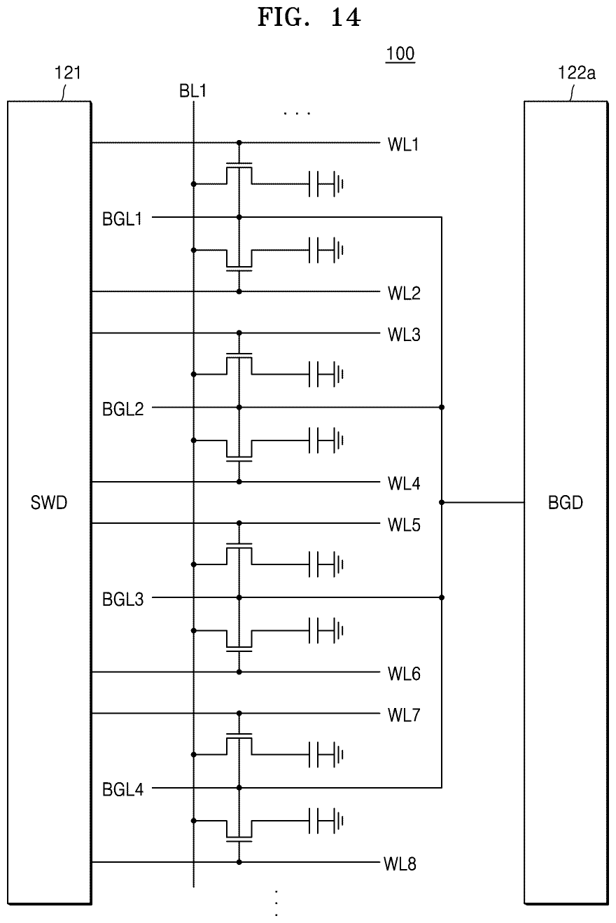

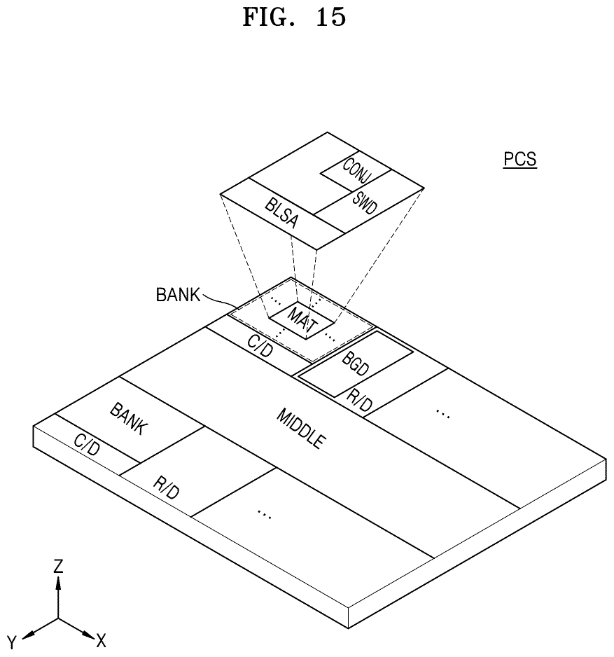

FIG. 14 is a diagram for explaining a back gate driver according to some embodiments of the present disclosure. FIG. 15 is a diagram schematically showing the structure of the back gate driver of FIG. 14.

Referring to FIGS. 3 and 14, the sub word line driver 121 may be connected to a plurality of word lines, for example, the first to eighth word lines WL1, WL2, WL3, WL4, WL5, WL6, WL7, and WL8. A back gate driver 122a may be implemented as a single back gate driver connected to a plurality of back gate lines, for example, the first to fourth back gate lines BGL1, BGL2, BGL3, and BGL4. The back gate driver 122a may apply a back gate voltage to each of a plurality of back gate lines, for example, the first to fourth back gate lines BGL1, BGL2, BGL3, and BGL4. That is, in the active period ACT, the potentials of all back gate lines BGL may be reduced from the first voltage level to the second voltage level.

Referring to FIGS. 2 and 15, a middle area MIDDLE of a peripheral circuit structure PCS may include a command decoder, an address buffer, and a data input/output circuit. Each of areas other than the middle area MIDDLE of the peripheral circuit structure PCS may include a row decoder R/D, a column decoder C/D, and a bank BANK. The row decoder R/D may include a back gate driver BGD. The back gate driver BGD of FIG. 15 may correspond to the back gate driver 122a of FIG. 14. The bank BANK may include one or more mats MAT. One mat MAT may include a bit line sense amplifier BLSA and a sub word line driver SWD. One mat MAT may further include a conjunction CONJ.

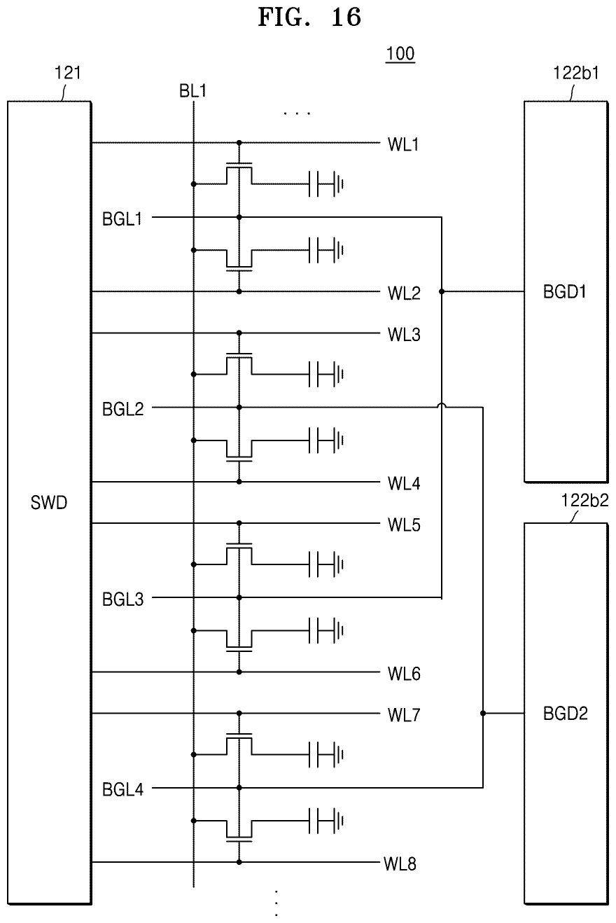

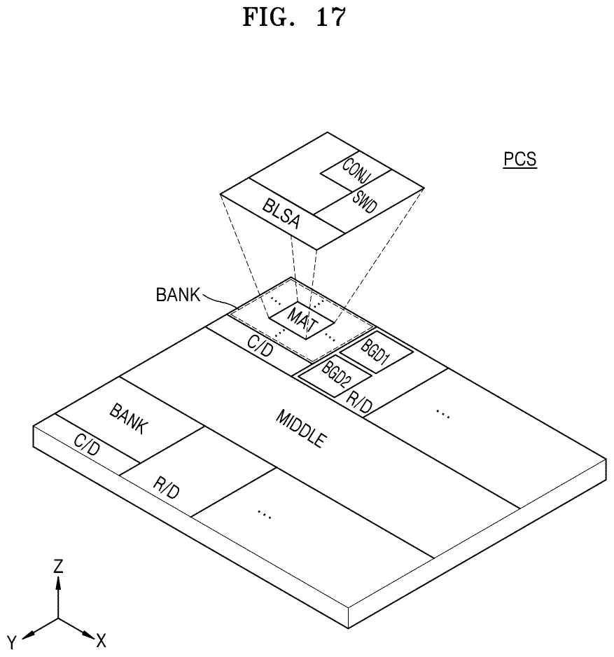

FIG. 16 is a diagram for explaining a back gate driver according to some embodiments. FIG. 17 is a diagram schematically showing a structure of the back gate driver of FIG. 16.

Referring to FIGS. 3 and 16, the plurality of back gate lines may include a first back gate line group including first back gate lines and a second back gate line group including second back gate lines. For example, the first back gate line group may include odd-numbered back gate lines and the second back gate line group may include even-numbered back gate lines. Referring to FIG. 16, for example, the odd-numbered back gate lines include a first back gate line BGL1, a third back gate line BGL3, etc., and the even-numbered back gate lines include a second back gate line BGL2, a fourth back gate line BGL4, etc. A first back gate driver 122b1 may be connected to each of the first back gate lines, for example, the first back gate line BGL1 and the third back gate line BGL3. A second back gate driver 122b2 may be connected to each of the second back gate lines, for example, the second back gate line BGL2 and the fourth back gate line BGL4. Depending on whether the number of selected word lines is odd or even, the potential of the corresponding back gate line may be changed between a first voltage level and a second voltage level by the first back gate driver 122b1 or the second back gate driver 122b2.

Referring to FIGS. 2 and 17, the peripheral circuit structure PCS may be the same as the peripheral circuit structure PCS described above with reference to FIG. 16. Each of the areas other than the middle area MIDDLE of the peripheral circuit structure PCS may include a row decoder R/D, a column decoder C/D, and a bank BANK. The row decoder R/D may include a first back gate driver BGD1 and a second back gate driver BGD2. The first and second back gate drivers BGD1 and BGD2 of FIG. 17 may correspond to the first back gate driver 122b1 and the second back gate driver 122b2 of FIG. 16.

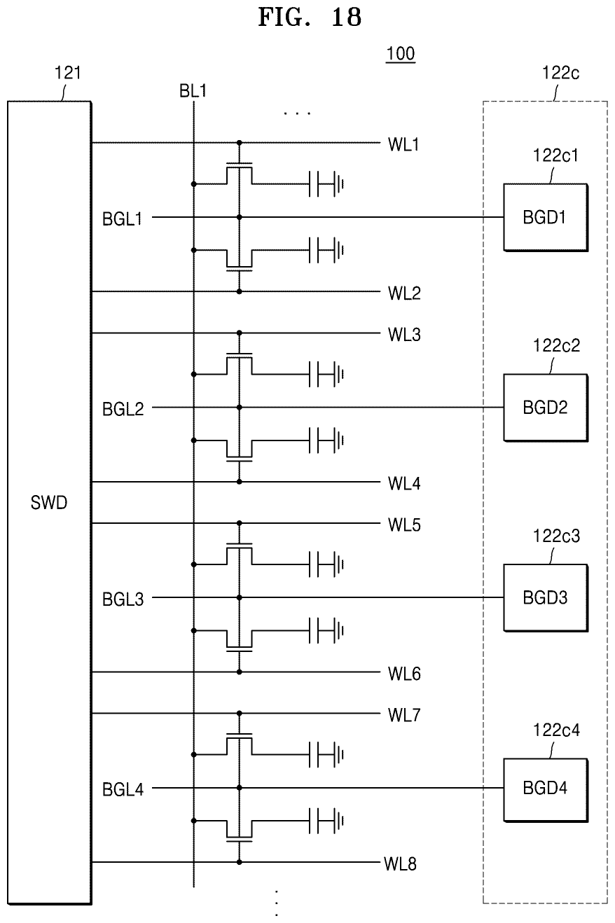

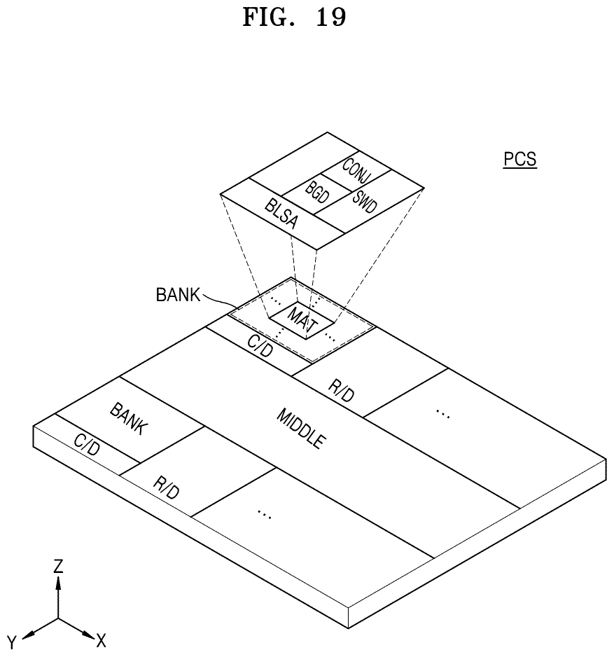

FIG. 18 is a diagram for explaining a back gate driver according to someembodiments. FIG. 19 is a diagram schematically showing a structure of the back gate driver of FIG. 18.

Referring to FIGS. 3 and 18, a back gate driver group 122c may include a plurality of back gate drivers connected respectively to each of a plurality of back gate lines. For example, a first back gate driver 122cl is connected to a first back gate line BGL1, a second back gate driver 122c2 is connected to a second back gate line BGL2, a third back gate driver 322c3 is connected to a third back gate line BGL3, and a fourth back gate driver 422c4 is connected to a fourth back gate line BGL4. According to the number of selected word lines, the potential of the corresponding back gate line may be changed between the first voltage level and the second voltage level by the back gate driver connected to the back gate line corresponding to the selected word line within the active period ACT.

Referring to FIGS. 2 and 19, the peripheral circuit structure PCS is the same as the peripheral circuit structure PCS described above with reference to FIG. 16. Each of the areas other than the middle area MIDDLE of the peripheral circuit structure PCS may include a row decoder R/D, a column decoder C/D, and a bank BANK. One mat MAT may include a bit line sense amplifier BLSA, a sub word line driver SWD, a conjunction CONJ, and a back gate driver BGD. The back gate driver BGD of FIG. 19 may correspond to the back gate driver group 122c of FIG. 18.

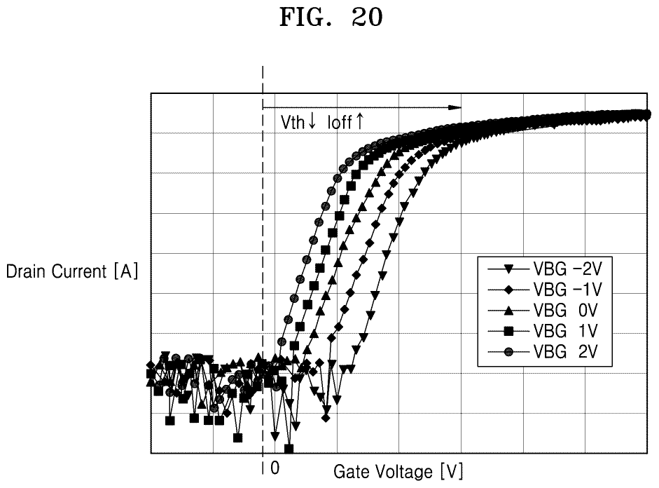

FIG. 20 is a graph illustrating a current according to a back gate voltage according to some embodiments.

Referring to FIG. 20, a second voltage level of a back gate voltage VBG may be set differently for each memory device 100. For example, depending on the memory device, the back gate voltage VBG may be set to 2 [V], 1[V], 0[V], −1[V], or −2[V]. However, the setting of the back gate voltage VBG is not limited thereto. As the second voltage level of the back gate voltage VBG gradually decreases, a voltage level of a threshold voltage Vth may increase. Additionally, as the second voltage level of the back gate voltage VBG gradually decreases, a leakage current may decrease.

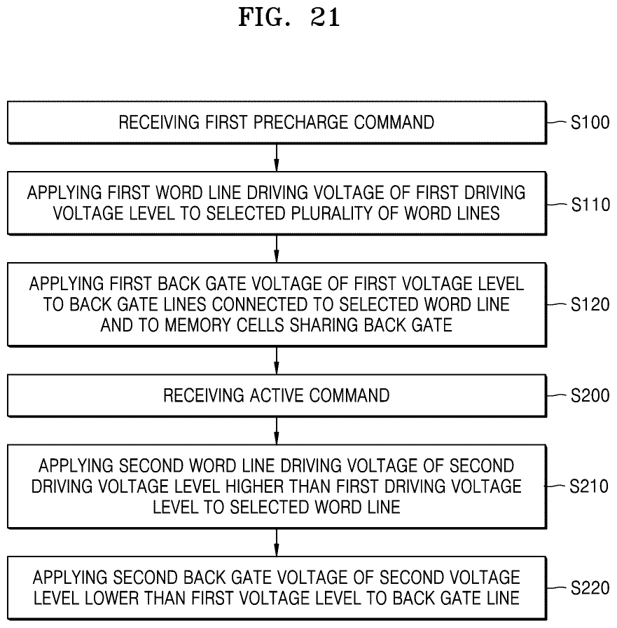

FIG. 21 is a flowchart illustrating a method of operating the memory device 100, according to some embodiments.

Referring to FIG. 21, in operation S100, the memory device 100 may receive a first precharge command.

In operation S110, the memory device 100 may apply a first word line driving voltage having a first driving voltage level to a plurality of word lines. For example, in the first precharge period PCG1, the first word line driving voltage having the first driving voltage level may be applied to a plurality of word lines. In another example, the first word line driving voltage having the first driving voltage level may be applied to the enabled word line in the active period ACT before the first precharge period PCG1.

In operation S120, the memory device 100 may apply a first back gate voltage having a first voltage level to a plurality of back gate lines. For example, in the first precharge period PCG1, a first back gate voltage having the first voltage level may be applied to a plurality of back gate lines.

In operation S200, the memory device 100 may receive an active command.

In operation S210, the memory device 100 may apply a second word line driving voltage having a second driving voltage level that is higher than the first driving voltage level to a word line selected from among a plurality of word lines. For example, in the active period ACT after the first precharge period PCG1, the second word line driving voltage having the second driving voltage level may be applied to the selected word line (e.g., the second word line WL2).

In operation S220, the memory device 100 may apply a second back gate voltage having a second voltage level that is lower than the first voltage level to a back gate line BGL connected to the selected word line and connected to memory cells sharing the back gate line BGL. For example, a second back gate voltage having the second voltage level may be applied to a back gate line (e.g., the first back gate line BGL1) connected to a selected word line (e.g., the second word line WL2) and connected to memory cells sharing the back gate line BGL.

In some embodiments, the active period ACT may include a charge sharing period CS and a sensing period and restoring period S&R. In operation S220, the memory device 100 may change the first back gate voltage to the second back gate voltage within the charge sharing period CS.

In some embodiments, the active period ACT may include an offset cancellation period OC, a charge sharing period CS, and a sensing period and restoring period S&R. In operation S220, the memory device 100 may change the first back gate voltage to the second back gate voltage within the offset cancellation period.

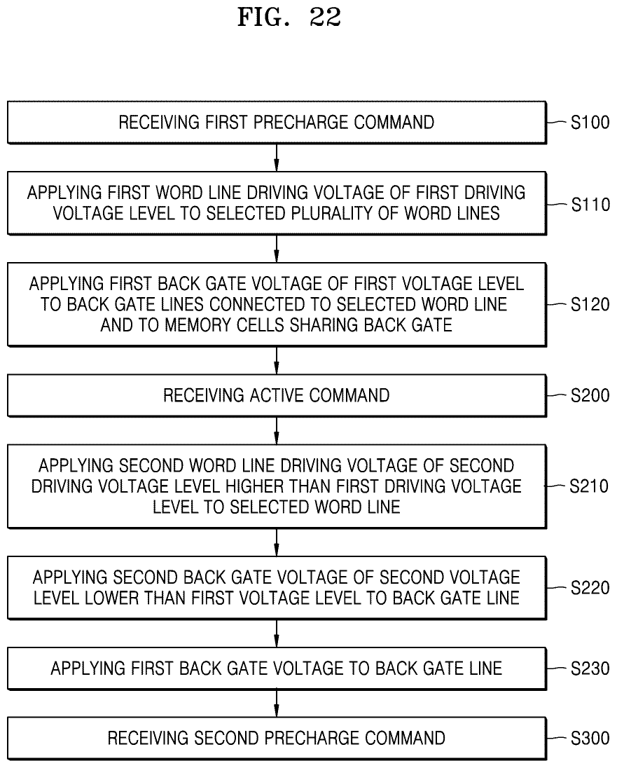

FIG. 22 is a flowchart illustrating a method of operating the memory device 100 according to some embodiments.

Referring to FIGS. 21 and 22, the method of FIG. 22 may further include operation S230 and operation S300.

In operation S230 after operation S220, the memory device 100 may apply the first back gate voltage to the back gate line BGL within the active period ACT.

In operation S300, the memory device 100 may receive a second precharge command.

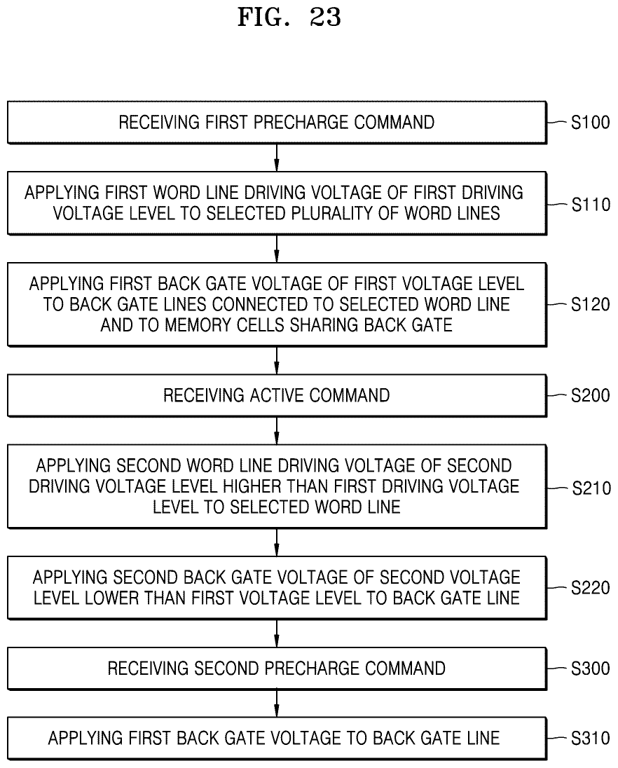

FIG. 23 is a flowchart illustrating a method of operating the memory device 100 according to some embodiments.

Referring to FIGS. 21 and 23, the method of FIG. 23 may further include operation S300 and operation S310. Operation S300 is the same as described above with reference to FIG. 22. In operation S310 after operation S300, the memory device 100 may apply the first back gate voltage to the back gate line BGL within the second precharge period PCG2.

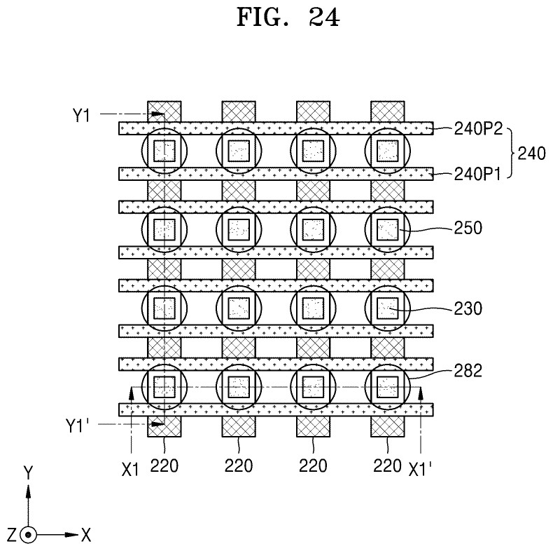

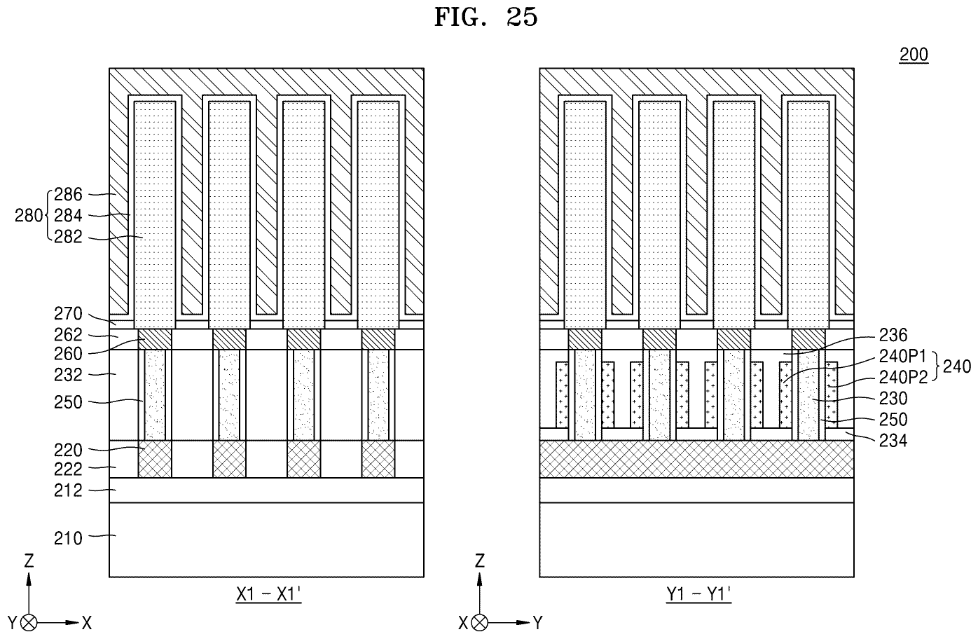

FIG. 24 is a diagram showing a layout of an integrated circuit device 200 according to some embodiments. FIG. 25 is a cross-sectional view taken along lines X1-X1′ and Y1-Y1′ of FIG. 24.

Referring to FIGS. 24 and 25, the integrated circuit device 200 may include a substrate 210, a plurality of first conductive lines 220, a channel layer 230, a gate electrode 240, a gate insulating layer 250, and a capacitor structure 280. The integrated circuit device 200 may include a memory device including a vertical channel transistor VCT. The vertical channel transistor VCT may refer to a structure in which a channel length of the channel layer 230 extends from the substrate 210 in the vertical direction.

A lower insulating layer 212 may be on the substrate 210, and the plurality of first conductive lines 220 may be spaced apart from each other in the first direction (X direction) and extend in the second direction (Y direction) on the lower insulating layer 212. A plurality of first insulating patterns 222 may be arranged on the lower insulating layer 212 and may be in (e.g., fill) spaces between the plurality of first conductive lines 220. The plurality of first insulating patterns 222 may extend in the second direction (Y direction), and upper surfaces of the plurality of first insulating patterns 222 may be at the same level as (e.g., coplanar with) upper surfaces of the plurality of first conductive lines 220.

The plurality of first conductive lines 220 may function as bit lines of the integrated circuit device 200. In example embodiments, the plurality of first conductive lines 220 may include doped polysilicon, metal, conductive metal nitride, conductive metal silicide, conductive metal oxide, or a combination thereof. For example, the plurality of first conductive lines 220 may include doped polysilicon, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, IrOx, or RuOx, or a combination of two or more thereof, but the present disclosure is not limited thereto. The plurality of first conductive lines 220 may include a single layer or multiple layers of the above-described materials. In some embodiments, the plurality of first conductive lines 220 may include a two-dimensional semiconductor material, for example, graphene or carbon nanotube, or a combination of two or more thereof.

The channel layers 230 may be arranged in a matrix form in which the channel layers 230 are spaced apart in the first direction (X direction) and the second direction (Y direction) and may be on the plurality of first conductive lines 220. The channel layer 230 may have a first width in the first direction (X direction) and a first height in the third direction (Z direction), wherein the first height may be greater than the first width. For example, the first height may be in a range from about 2 times to about 10 times the first width, but the present disclosure is not limited thereto. A bottom portion of the channel layer 230 functions as a first source/drain region (not shown), and an upper portion of the channel layer 230 functions as a second source/drain region (not shown), and a portion of the channel layer 230 between the first and second source/drain regions may function as a channel region (not shown).

In example embodiments, the channel layer 230 may include an oxide semiconductor. For example, the oxide semiconductor may include InₓGa_{y}Zn_{z}, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, or InₓGa_{y}O, or a combination of two or more thereof. The channel layer 230 may include a single layer or multiple layers of the oxide semiconductor. In some embodiments, the channel layer 230 may have a bandgap energy that is greater than that of silicon. For example, the channel layer 230 may have a bandgap energy that is in a range from about 1.5 eV to about 5.6 eV. For example, the channel layer 230 may have relatively optimal channel performance when the channel layer 230 has a band gap energy in a range from about 2.0 eV to about 4.0 eV. For example, the channel layer 230 may be polycrystalline or amorphous, but the present disclosure is not limited thereto. In some embodiments, the channel layer 230 may include a two-dimensional semiconductor material, for example, the two-dimensional semiconductor material may include graphene, carbon nanotubes, or a combination of two or more thereof.

The gate electrodes 240 may extend in the first direction (X direction) on first and second sidewalls of the channel layer 230 (e.g., in the Y direction). The gate electrodes 240 may include a first sub-gate electrode 240P1 facing a first sidewall of the channel layer 230, and a second sub-gate electrode 240P2 facing a second sidewall opposite to the first sidewall of the channel layer 230. As one channel layer 230 is between the first sub-gate electrode 240P1 and the second sub-gate electrode 240P2, the integrated circuit device 200 may have a dual gate transistor structure. However, the present disclosure is not limited thereto, and the second sub-gate electrode 240P2 may be omitted and only the first sub-gate electrode 240P1 that faces the first sidewall of the channel layer 230 may be formed to form a single gate transistor structure. The gate electrode 240 may include doped polysilicon, metal, conductive metal nitride, conductive metal silicide, conductive metal oxide, or a combination thereof. For example, the gate electrode 240 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, or RuOx, or a combination of two or more thereof, but the present disclosure is not limited thereto.

The gate insulating layer 250 may surround the sidewalls of the channel layer 230 and may be located between the channel layer 230 and the gate electrode 240. For example, the entire sidewalls of the channel layer 230 may be surrounded by the gate insulating layer 250, and a portion of sidewalls of the gate electrode 240 may contact the gate insulating layer 250. In some embodiments, the gate insulating layer 250 may extend in an extending direction (e.g., the first direction (X direction)) of the gate electrode 240, and among the sidewalls of the channel layer 230, only the two sidewalls facing the gate electrode 240 may be in contact with the gate insulating layer 250.

In some embodiments, the gate insulating layer 250 may include a silicon oxide film, a silicon oxynitride film, or a high-k dielectric film having a higher dielectric constant than the silicon oxide film, or a combination of two or more thereof. The high-k dielectric film may include metal oxide or metal oxynitride. For example, the high-k dielectric film that may be used as or in the gate insulating layer 250 may include HfO₂, HfSiO, HfSION, HfTaO, HfTiO, HfZrO, ZrO₂, or Al₂O₃, or a combination of two or more thereof, but the present disclosure is not limited thereto.

A plurality of second insulating patterns 232 may extend in the second direction (Y direction) on the plurality of first insulating patterns 222, and each channel layer 230 may be between two adjacent second insulating patterns 232 among the plurality of second insulating patterns 232. Additionally, a first buried layer 234 and a second buried layer 236 may be in a space between two adjacent channel layers 230 between two adjacent second insulating patterns 232. The first buried layer 234 may be at a bottom part of the space between two adjacent channel layers 230, and the second buried layer 236 may be formed in (and may fill) a remaining space between two adjacent channel layers 230 on the first buried layer 234.

An upper surface of the second buried layer 236 may be at the same level as an upper surface of the channel layer 230, and the second buried layer 236 may cover the upper surface of the gate electrode 240. In some embodiments, the plurality of second insulating patterns 232 may be formed as a continuous material layer with the plurality of first insulating patterns 222, and/or the second buried layer 236 may be formed as a continuous material layer with the first buried layer 234.

A plurality of capacitor contacts 260 may be on each of the channel layers 230. The capacitor contacts 260 may be arranged to overlap vertically with the channel layers 230 and may be arranged in a matrix form in which the capacitor contacts 260 are spaced apart in the first direction (X direction) and the second direction (Y direction). The capacitor contact 260 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, or RuOx, or a combination of two or more thereof, but the present disclosure is not limited thereto. The upper insulating layer 262 may surround sidewalls of the capacitor contact 260 on the plurality of second insulating patterns 232 and the second buried layer 236.

An etch stop layer 270 may be on the upper insulating layer 262, and a capacitor structure 280 may be on the etch stop layer 270. The capacitor structure 280 may include a lower electrode 282, a capacitor dielectric layer 284, and an upper electrode 286.

The lower electrode 282 may penetrate or extend through the etch stop layer 270 and may be electrically connected to an upper surface of the capacitor contact 260. The lower electrode 282 may be formed as a pillar type extending in the third direction (Z direction), but the present disclosure is not limited thereto. In some embodiments, the lower electrode 282 may be arranged to overlap vertically with the capacitor contact 260 and may be arranged in a matrix form in which the lower electrodes 282 are spaced apart in the first direction (X direction) and the second direction (Y direction). In some embodiments, a landing pad (not shown) may be provided between the capacitor contact 260 and the lower electrode 282, and the lower electrodes 282 may be arranged in a hexagonal shape.

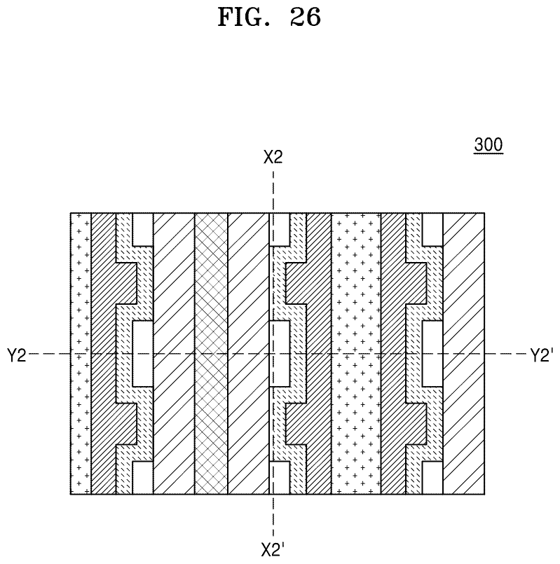

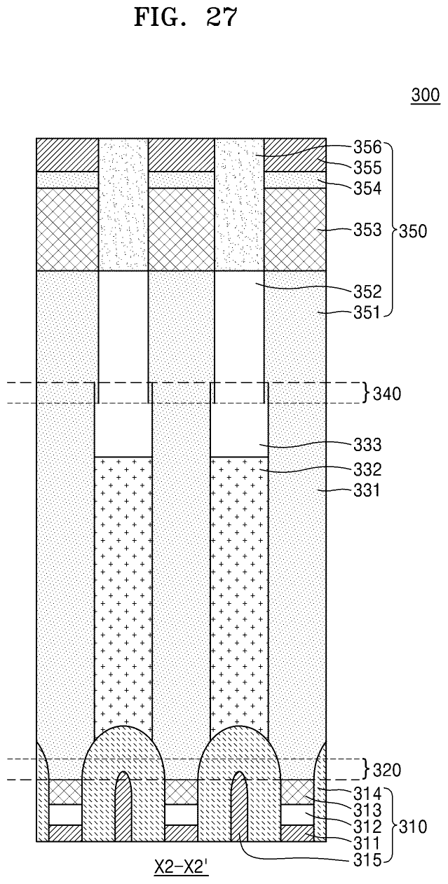

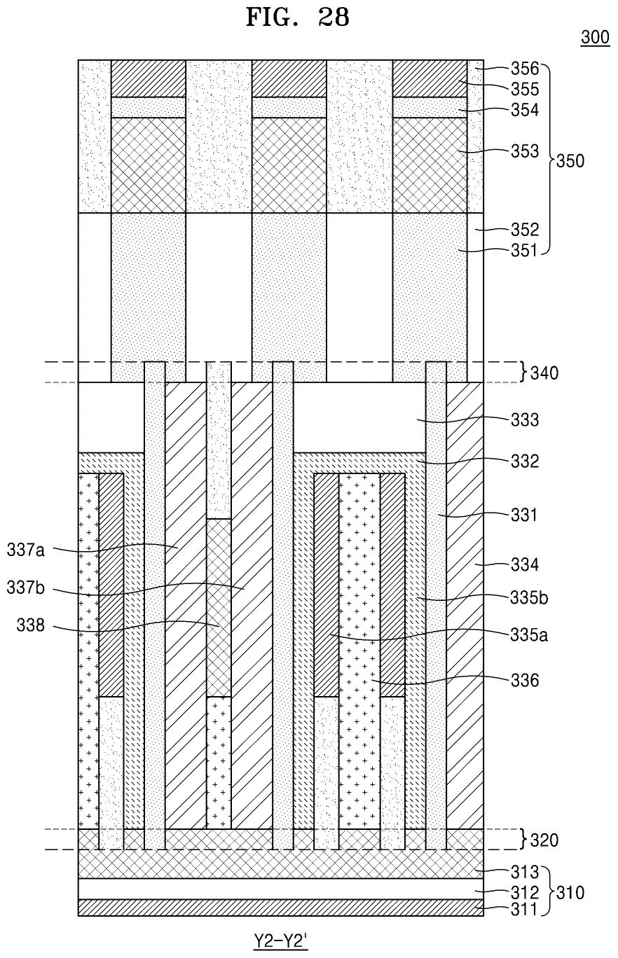

FIG. 26 is a diagram showing a layout of an integrated circuit device 300 according to some embodiments, FIG. 27 is a cross-sectional view taken along line X2-X2′ of FIG. 26, and FIG. 28 is a cross-sectional view taken along line Y2-Y2′ of FIG. 26.

Referring to FIGS. 26, 27, and 28, the integrated circuit device 300 may correspond to the memory device 100 of FIG. 1. The integrated circuit device 300 may include a lower substrate 310, a first recess 320, a channel layer 331, a forward gate insulating layer 332, a first insulating layer 333, first and second forward gates 335a and 335b, a word line insulating layer 336, first, second, and third back gate insulating layers 337a, 337b, and 334, a back gate 338, a second recess 340, and an upper substrate 350. The integrated circuit device 300 may be a memory device including a vertical channel transistor.

The lower substrate 310 may be formed, for example, based on silicon. The lower substrate 310 may include a bit line 311, a barrier metal (BM) layer 312, a first poly layer 313, a spacer 314, and a shield 315. The bit line 311, the BM layer 312, and the first poly layer 313 may be sequentially stacked. The spacer 314 and the shield 315 may be between stack structures including the bit line 311, the BM layer 312, and the first poly layer 313. The spacer 314 may have a convex shape toward the upper substrate 350. The shield 315 may be inside the spacer 314. A structure from an upper surface of the shield 315 to an upper surface of the spacer 314 may be referred to as a bit line recess.

The first recess 320 may be a direct contact (DC) field oxide recess and may be arranged at a constant distance from the lower substrate 310 toward the upper substrate 350.

The channel layer 331 may be a vertical channel of a vertical channel transistor. The channel layer 331 may include an oxide semiconductor and may include a single layer or multiple layers of the oxide semiconductor. For example, the channel layer 331 may be polycrystalline or amorphous, but the present disclosure is not limited thereto. The forward gate insulating layer 332 may correspond to the gate insulating layer 250. The first insulating layer 333 may be on the forward gate insulating layer 332. The first and second forward gates 335a and 335b may correspond to the first and second sub-gate electrodes 240P1 and 240P2. The word line insulating layer 336 may be between the first and second forward gates 335a and 335b. The first and second back gate insulating layers 337a and 337b may be formed on and may surround the back gate 338. The third back gate insulating layer 334 may be formed on and may surround another back gate (not shown) with a fourth back gate insulating layer (not shown). The back gate 338 may be provided in the vertical channel transistor described above and may be shared with adjacent vertical channel transistors.

The second recess 340 may be a buried contact (BC) field oxide recess and may be formed from the first insulating layer 333 to the upper substrate 350.

The upper substrate 350 includes a second poly layer 351, a second insulating layer 352, a buried contact (BC) layer 353, a metal silicide layer 354, a metal layer 355, and a third insulating layer 356. The second poly layer 351 may be a layer composed of gradually doped poly, and may be on the second recess 340 and the channel layer 331. The second insulating layer 352 may be between the second poly layers 351. The BC layer 353 may be on the second poly layer 351. The metal silicide layer 354 may be on the BC layer 353 and may include, for example, cobalt silicide (CoSiₓ). The metal layer 355 may be formed by mixing BM and other metals, and may be on the metal silicide layer 354. The third insulating layer 356 may be between stack structures including the BC layer 353, the metal silicide layer 354, and the metal layer 355.

It may be apparent to those skilled in the art that the structure of the present disclosure may be modified or changed in various ways without departing from the scope or technical spirit of the present disclosure. In view of the foregoing, the present disclosure is intended to include modifications and changes to the present disclosure that fall within the scope of the following claims and equivalents.

While the inventive concept has been particularly shown and described with reference to some examples of embodiments thereof, it will be understood that various changes in form and details may be made therein without departing from the scope of the following claims.

The invention claimed is:

1. A memory device comprising:
a plurality of memory cells, each memory cell including a cell transistor having a back gate that is shared with a cell transistor of an adjacent memory cell and connected to a back gate line, a forward gate that is connected to a corresponding word line, and a cell capacitor that is connected to a first electrode of the cell transistor;
a sub-word line driver configured to apply a word line driving voltage to a selected word line;
a back gate driver configured to change a voltage level of a back gate voltage applied to a back gate line corresponding to the selected word line from a first voltage level to a second voltage level during an active period in which the selected word line is enabled; and
a sense amplifier configured to sense data through bit lines connected to second electrodes of the cell transistors of the plurality of memory cells.

2. The memory device of claim 1, wherein the active period includes a charge sharing period, a sensing period, and a restoring period, and
wherein a voltage level of the back gate voltage is changed from the first voltage level to the second voltage level within the charge sharing period.

3. The memory device of claim 2, wherein the voltage level of the back gate voltage is changed from the second voltage level to the first voltage level within the sensing period or the restoring period.

4. The memory device of claim 1, wherein the voltage level of the back gate voltage is changed from the second voltage level to the first voltage level within the active period or within a precharge period in which the selected word line is disabled, the precharge period after the active period.

5. The memory device of claim 1, wherein the active period includes an offset cancellation period, a charge sharing period, a sensing period, and a restoring period, and
wherein the voltage level of the back gate voltage is changed from the first voltage level to the second voltage level within the offset cancellation period or the charge sharing period.

6. The memory device of claim 1, wherein the plurality of memory cells include:
a first memory cell including a first cell transistor connected to a first word line, a first bit line, and a first back gate line, the first memory cell further including a first cell capacitor connected between a first electrode of the first cell transistor and a ground;
a second memory cell including a second cell transistor connected to a second word line adjacent to the first word line, the first bit line, and the first back gate line, the second memory cell further including a second cell capacitor connected between a first electrode of the second cell transistor and the ground; and
a third memory cell including a third cell transistor connected to a third word line adjacent to the second word line, the first bit line, and a second back gate line, the third memory cell further including a third cell capacitor connected between a first electrode of the third cell transistor and the ground.

7. The memory device of claim 6, wherein the first voltage level is higher than the second voltage level, and
wherein during the active period in which the second word line is enabled, a voltage level of the back gate voltage applied to the first back gate line decreases from the first voltage level to the second voltage level.

8. The memory device of claim 7, wherein, during the active period in which the second word line is enabled, a voltage level of a third word line driving voltage applied to the third word line decreases.

9. The memory device of claim 1, wherein the cell transistor includes an n-type transistor,
wherein the second voltage level is lower than the first voltage level,
wherein during the active period, the voltage level of the word line driving voltage increases from a first driving voltage level to a third driving voltage level that is higher than a second driving voltage level for turning on the cell transistor, and
wherein during the active period, the voltage level of the back gate voltage decreases from the first voltage level to the second voltage level.

10. A memory device comprising:
a cell array structure including a plurality of word lines, a plurality of bit lines, a plurality of back gate lines, and a plurality of memory cells, each memory cell configured to share a back gate with an adjacent memory cell through a back gate line connected thereto; and
a peripheral circuit structure including a peripheral circuit configured to apply a word line driving voltage to a selected word line among the plurality of word lines, configured to apply a back gate voltage to a back gate line that is connected to memory cells connected to the selected word line, and configured to sense data through at least one selected bit line among the plurality of bit lines, the peripheral circuit structure overlapping vertically with at least a portion of the cell array structure,
wherein the peripheral circuit is configured to change a voltage level of the back gate voltage from a first voltage level to a second voltage level within an active period in which the selected word line is enabled.

11-13. (canceled)

14. The memory device of claim 10, wherein the voltage level of the back gate voltage is changed from the second voltage level to the first voltage level within the active period or a second precharge period after the active period in which the selected word line is disabled.

15. The memory device of claim 10, wherein the peripheral circuit includes a single back gate driver that is connected to the plurality of back gate lines and that is configured to apply the back gate voltage to each of the plurality of back gate lines.

16. The memory device of claim 10, wherein the plurality of back gate lines includes a first back gate line group including first back gate lines, and a second back gate line group including second back gate lines, and
wherein the peripheral circuit includes a first back gate driver connected to each of the first back gate lines and a second back gate driver connected to each of the second back gate lines.

17. The memory device of claim 10, wherein the peripheral circuit includes a plurality of back gate drivers connected respectively to each of the plurality of back gate lines.

18. The memory device of claim 10, wherein, during the active period, a voltage level of the word line driving voltage that is applied to the selected word line decreases.

19. The memory device of claim 10, wherein the second voltage level is lower than the first voltage level,
wherein the voltage level of the word line driving voltage increases from a first driving voltage level to a third driving voltage level that is higher than a second driving voltage level during the active period, and
wherein the voltage level of the back gate voltage decreases from the first voltage level to the second voltage level during the active period.

20. The memory device of claim 10, wherein the plurality of memory cells include:
a first memory cell including a first vertical channel transistor connected to a first word line, a first bit line, and a first back gate line, and a first cell capacitor connected between a first electrode of the first vertical channel transistor and a ground;
a second memory cell including a second vertical channel transistor connected to a second word line adjacent to the first word line, the first bit line, and the first back gate line, and a second cell capacitor connected between a first electrode of the second vertical channel transistor and the ground; and
a third memory cell including a third vertical channel transistor connected to a third word line adjacent to the second word line, the first bit line, and a second back gate line, and a third cell capacitor connected between a first electrode of the third vertical channel transistor and the ground.

21. A method of operating a memory device, the method comprising:
during a first precharge period, applying a first word line driving voltage of a first driving voltage level to a plurality of word lines;
during the first precharge period, applying a first back gate voltage of a first voltage level to a plurality of back gate lines;
during an active period after the first precharge period, applying a second word line driving voltage of a second driving voltage level higher than the first driving voltage level to a selected word line among the plurality of word lines; and
during the active period, applying a second back gate voltage of a second voltage level which is lower than the first voltage level to a back gate line among the plurality of back gate lines corresponding to the selected word line and connected to memory cells sharing a back gate.

22. The method of claim 21, further comprising, after applying the second back gate voltage to the back gate line corresponding to the selected word line, applying the first back gate voltage to the back gate line corresponding to the selected word line during the active period.

23. The method of claim 21, further comprising, during a second precharge period after the active period, applying the first back gate voltage to the back gate line corresponding to the selected word line.

24-25. (canceled)
